(19) United States
(12) Patent Application Publication
(10) Pub. No.: US 2026/0114131 A1
(43) Pub. Date: Apr. 23, 2026

(54) DISPLAY DEVICE AND MANUFACTURING METHOD OF DISPLAY DEVICE

(71) Applicant: Magnolia White Corporation, Tokyo (JP)

(72) Inventors: Akinori KAMIYA, Tokyo (JP); Hiraaki KOKAME, Tokyo (JP)

(73) Assignee: Magnolia White Corporation, Tokyo (JP)

(21) Appl. No.: 19/361,027

(22) Filed: Oct. 17, 2025

(30) Foreign Application Priority Data
Oct. 17, 2024 (JP) 2024-181884

(51) Int. Cl. H10K 59/122; H10K 59/12

(52) U.S. Cl. CPC H10K 59/122; H10K 59/1201

(57) ABSTRACT

According to one embodiment, a display device includes a substrate, a display element provided above the substrate, an inorganic insulating layer having an aperture overlapping the display element, a partition provided on the inorganic insulating layer, formed in an overhang shape, and surrounding the display element, a bank provided on the partition and surrounding the display element, and a first sealing layer formed of an inorganic insulating material, overlapping the display element and the bank, extending above the partition, and forming a gap between the first sealing layer and the partition.

### CROSS-REFERENCE TO RELATED APPLICATIONS

This application is based upon and claims the benefit of priority from Japanese Patent Application No. 2024-181884, filed Oct. 17, 2024, the entire contents of which are incorporated herein by reference.

### FIELD

Embodiments described herein relate generally to a display device and a manufacturing method of a display device.

### BACKGROUND

Recently, display devices with organic light-emitting diodes (OLED) applied thereto as display elements have been put into practical use. In this type of display devices, a technique for suppressing decreases in reliability is required.

### BRIEF DESCRIPTION OF THE DRAWINGS

FIG. 1 is a view showing a configuration example of a display device DSP.

FIG. 2 is a diagram showing an example of the layout of subpixels SP1, SP2, and SP3 which constitute one pixel PX.

FIG. 3 is a schematic cross-sectional view of the display device DSP along the A-B line of FIG. 2.

FIG. 4 is a cross-sectional view showing a partition 6 between a display element DE1 and a display element DE2 in an enlarged manner.

FIG. 5A is a view for explanations on a manufacturing method of the display device DSP shown in FIG. 3.

FIG. 5B is a view for explanations on the manufacturing method of the display device DSP.

FIG. 5C is a view for explanations on the manufacturing method of the display device DSP.

FIG. 5D is a view for explanations on the manufacturing method of the display device DSP.

FIG. 5E is a view for explanations on the manufacturing method of the display device DSP.

FIG. 5F is a view for explanations on the manufacturing method of the display device DSP.

FIG. 5G is a view for describing a manufacturing method of the display device DSP.

FIG. 5H is a view for describing the manufacturing method of the display device DSP.

FIG. 5I is a view for describing the manufacturing method of the display device DSP.

FIG. 5J is a view for describing the manufacturing method of the display device DSP.

FIG. 6 is a view showing another configuration example of the layout of a bank BK.

FIG. 7 is a schematic cross-sectional view of the display device DSP along the A-B line of FIG. 6.

FIG. 8 is a view showing another configuration example of the layout of the bank BK.

FIG. 9 is a schematic cross-sectional view of the display device DSP along the A-B line of FIG. 8.

FIG. 10 is a view showing another configuration example of the display device DSP.

FIG. 11A is a view for explanations on a manufacturing method of the display device DSP shown in FIG. 10.

FIG. 11B is a view for explanations on the manufacturing method of the display device DSP.

FIG. 11C is a view for explanations on the manufacturing method of the display device DSP.

FIG. 11D is a view for explanations on the manufacturing method of the display device DSP.

FIG. 11E is a view for explanations on the manufacturing method of the display device DSP.

FIG. 11F is a view for explanations on the manufacturing method of the display device DSP.

FIG. 11G is a view for describing the manufacturing method of the display device DSP.

FIG. 11H is a view for describing the manufacturing method of the display device DSP.

FIG. 11I is a view for describing the manufacturing method of the display device DSP.

FIG. 12 is a view showing another configuration example of the display device DSP.

FIG. 13 is a view showing another configuration example of the display device DSP.

### DETAILED DESCRIPTION

An object of the embodiment is to provide a display device capable of suppressing decreases in reliability and a manufacturing method of the display device.

In general, according to one embodiment, a display device includes a substrate, a display element provided above the substrate, an inorganic insulating layer having an aperture overlapping the display element, a partition provided on the inorganic insulating layer, formed in an overhang shape, and surrounding the display element, a bank provided on the partition and surrounding the display element, and a first sealing layer formed of an inorganic insulating material, overlapping the display element and the bank, extending above the partition, and forming a gap between the first sealing layer and the partition.

According to another embodiment, a display device includes a substrate, a display element provided above the substrate, an inorganic insulating layer having an aperture overlapping the display element, a partition provided on the inorganic insulating layer, formed in an overhang shape, and surrounding the display element, a first sealing layer formed of an inorganic insulating material, overlapping the display element, extending above the partition, and forming a gap between the first sealing layer and the partition, a filler filling the gap, and a first resin layer provided on the first sealing layer and formed of a material different from the filler.

According to still another embodiment, a display device manufacturing method includes steps of preparing a processing substrate by forming a lower electrode above a substrate, forming an inorganic insulating layer covering a periphery portion of the lower electrode, and forming a partition having an overhang shape and located on the inorganic insulating layer, forming a loop-shaped bank on the partition, performing a vapor deposition using the partition as a mask to form a stacked film including an organic layer including a light emitting layer, an upper electrode, and a cap layer, the stacked film being divided into a part overlapping the lower electrode within an area surrounded by the partition and the bank, a part overlapping the bank above the partition, and a part not overlapping the bank above the partition, depositing an inorganic insulating material to form a first sealing layer covering the stacked film, the partition, and the bank, forming a resist patterned into a predetermined shape on the first sealing layer, patterning the first sealing layer and the stacked film using the resist as a mask, and removing the resist.

According to still another embodiment, a display device manufacturing method includes steps of preparing a processing substrate by forming a lower electrode above a substrate, forming an inorganic insulating layer covering a periphery portion of the lower electrode, and forming a partition having an overhang shape and located on the inorganic insulating layer, performing a vapor deposition using the partition as a mask to form a stacked film including an organic layer including a light emitting layer, an upper electrode, and a cap layer, the stacked film being divided into a part overlapping the lower electrode within an area surrounded by the partition and a part overlapping the partition, depositing an inorganic insulating material to form a first sealing layer covering the stacked film and the partition, forming a resist patterned into a predetermined shape on the first sealing layer, patterning the first sealing layer and the stacked film using the resist as a mask, removing the resist, and filling a gap formed between the partition and the first sealing layer with a filler, the gap being formed by removing the part overlapping the partition of the stacked film.

Embodiment can provide a display device capable of suppressing decreases in reliability and a manufacturing method of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above”, “between”, and “face” are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

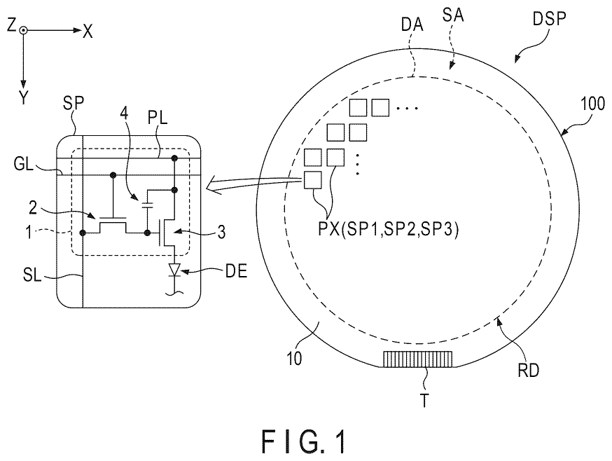

FIG. 1 is a view showing a configuration example of a display device DSP.

The display device DSP comprises a display panel 100. The display panel 100 has a display area DA for displaying images and a surrounding area SA around the display area DA on an insulating substrate 10. The substrate 10 may be either a glass substrate or a resinous substrate having flexibility.

The outer edge of at least a part of the display area DA has a round portion RD. In the illustrated example, the display area DA has a circular shape in plan view. The shape of the display area DA in plan view is not limited to the illustrated example. For example, the outer edge of the display area DA may be constituted by the round portion RD and a straight portion.

The display area DA comprises a plurality of pixels PX arranged in a matrix in the first direction X and the second direction Y. Each pixel PX includes a plurality of subpixels SP that display different colors. For example, each pixel PX includes a subpixel SP1, which displays the first color, a subpixel SP2, which displays the second color, and a subpixel SP3, which displays the third color. The first color, the second color, and the third color are different colors. Each pixel PX may include a subpixel SP, which displays another color such as white in addition to the subpixels SP1, SP2, and SP3 or instead of one of the subpixels SP1, SP2, and SP3.

The round portion RD in the display area DA is a shape in a macroscopic scale. In a microscopic scale, this shape is formed by providing a plurality of pixels PX in a stair step layout.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode or a drain electrode of the pixel switch 2 is connected to a signal line SL. The other is connected to a gate electrode of the drive transistor 3 and the capacitor 4. In the drive transistor 3, one of the source electrode and the drain electrode is connected to a power line PL and the capacitor 4. The other is connected to the display element DE. In the illustrated example, the scanning line GL and the power line PL extend in the first direction X and the signal line SL extends in the second direction Y.

The configuration of the pixel circuit 1 is not limited to the illustrated example. For example, the pixel circuit 1 may comprise more thin-film transistors and capacitors.

For example, the display element DE is an organic light emitting diode (OLED) as a light emitting element and thus may be called an organic EL element.

The display device DSP further comprises a terminal portion T provided in the surrounding area SA. The terminal portion T comprises a plurality of terminals. For example, the terminal portion T is electrically connected to an IC chip or a flexible printed circuit board for driving the display elements DE.

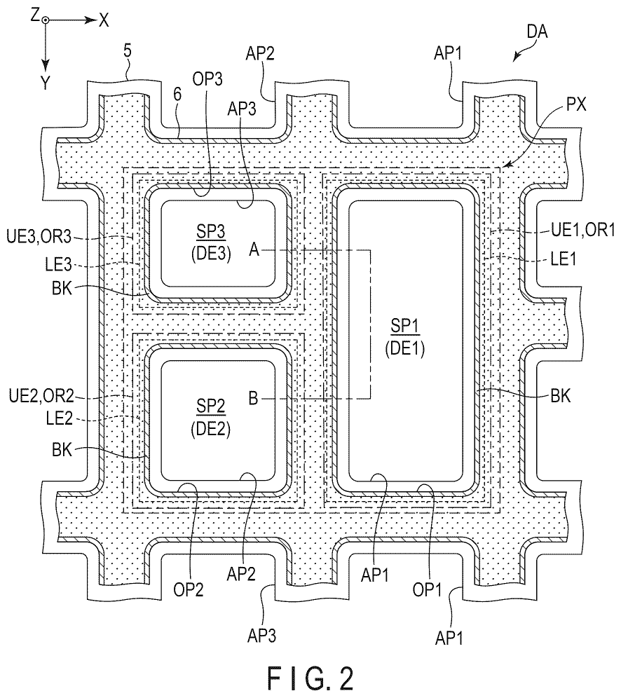

FIG. 2 is a diagram showing an example of the layout of the subpixels SP1, SP2, and SP3 which constitute one pixel PX.

In the illustrated example, the subpixels SP2 and SP3 are arranged in the second direction Y. Further, the subpixels SP1 and SP2 are arranged in the first direction X, and the subpixel SP1 and SP3 are arranged in the first direction X.

When the subpixels SP1, SP2, and SP3 are arranged in this layout, in the display area DA, a column in which the subpixels SP2 and SP3 are alternately arranged in the second direction Y and a column in which the plurality of subpixels SP1 are arranged in the second direction Y are formed. These columns are alternately arranged in the first direction X. The layout of the subpixels SP1, SP2, and SP3 is not limited to the illustrated example.

An inorganic insulating layer 5 and a partition 6 are provided in the display area DA. The inorganic insulating layer 5 has apertures AP1, AP2, and AP3 in the respective subpixels SP1, SP2, and SP3. The inorganic insulating layer 5 having these apertures AP1, AP2, and AP3 may be called a rib.

The partition 6 overlaps the inorganic insulating layer 5 in plan view. The partition 6 is formed in a grating shape surrounding the apertures AP1, AP2, and AP3. In other words, the partition 6 has respective apertures OP1, OP2, and OP3 in the subpixels SP1, SP2, and SP3 in the same manner as the inorganic insulating layer 5. The aperture OP1 overlaps the aperture AP1. The aperture OP2 overlaps the aperture AP2. The aperture OP3 overlaps the aperture AP3. The partition 6 is conductive and is electrically connected to a terminal with common voltage at the terminal portion T shown in FIG. 1.

The subpixels SP1, SP2, and SP3 comprise respective display elements DE1, DE2, and DE3, as the display elements DE.

The display element DE1 of the subpixel SP1 comprises a lower electrode LE1, an upper electrode UE1, and an organic layer OR1, which overlap the aperture AP1. The peripheral portion of the lower electrode LE1 is covered with the inorganic insulating layer 5. The lower electrode LE1, the organic layer OR1, and the upper electrode UE1, which constitute the display element DE1 are surrounded by the partition 6 in plan view. The peripheral portion of each of the organic layer OR1 and the upper electrode UE1 overlaps the inorganic insulating layer 5 in plan view.

The display element DE2 of the subpixel SP2 comprises a lower electrode LE2, an upper electrode UE2, and an organic layer OR2, which overlap the aperture AP2. The peripheral portion of the lower electrode LE2 is covered with the inorganic insulating layer 5. The lower electrode LE2, the organic layer OR2, and the upper electrode UE2, which constitute the display element DE2 are surrounded by the partition 6 in plan view. The peripheral portion of each of the organic layer OR2 and the upper electrode UE2 overlaps the inorganic insulating layer 5 in plan view.

The display element DE3 of the subpixel SP3 comprises a lower electrode LE3, an upper electrode UE3, and an organic layer OR3, which overlap the aperture AP3. The peripheral portion of the lower electrode LE3 is covered with the inorganic insulating layer 5. The lower electrode LE3, the organic layer OR3, and the upper electrode UE3, which constitute the display element DE3 are surrounded by the partition 6 in plan view. The peripheral portion of each of the organic layer OR3 and the upper electrode UE3 overlaps the inorganic insulating layer 5 in plan view.

In the illustrated example, the outlines of the lower electrodes LE1, LE2, and LE3 are indicated by broken lines, and the outlines of the organic layers OR1, OR2, and OR3 and the upper electrodes UE1, UE2, and UE3 are indicated by short dashed lines. The outlines of the respective lower electrode, organic layer, and upper electrode shown in the figure may not reflect the exact shapes.

For example, the lower electrodes LE1, LE2, and LE3 correspond to the anodes of the display elements. The upper electrodes UE1, UE2, and UE3 correspond to the cathodes of the display elements or a common electrode and contact the partition 6.

The lower electrode LE1 is electrically connected to the pixel circuit 1 (refer to FIG. 1) of the subpixel SP1. The lower electrode LE2 is electrically connected to the pixel circuit 1 of the subpixel SP2. The lower electrode LE3 is electrically connected to the pixel circuit 1 of the subpixel SP3.

In the illustrated example, the planar size of the aperture AP1, the planar size of the aperture AP2, and the planar size of the aperture AP3 differ from each other. The planar size of the aperture AP1 is greater than that of the aperture AP2. The planar size of the aperture AP2 is greater than that of the aperture AP3. The magnitude relationship of the planar sizes of the apertures AP1, AP2, and AP3 is not limited to the illustrated example.

Each of a plurality of banks BK (convex bodies) overlaps the partition 6 and is formed in a loop shape. Each of the display elements DE1, DE2, and DE3 is surrounded by the partition 6 and the bank BK. The bank BK surrounding the display element DE1, the bank BK surrounding the display element DE2, and the bank BK surrounding the display element DE3 are spaced apart from each other.

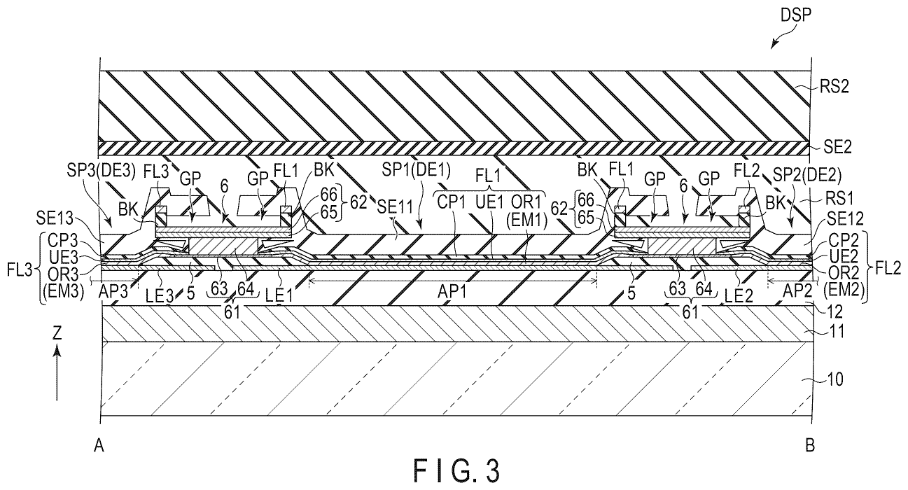

FIG. 3 is a schematic cross-sectional view of the display device DSP along the A-B line of FIG. 2.

A circuit layer 11 is provided on the substrate 10. The circuit layer 11 includes various circuits such as the pixel circuits 1 shown in FIG. 1, various lines such as the scanning line GL, the signal line SL, and the power line PL, and various insulating layers.

The organic insulating layer 12 is provided on the circuit layer 11. For example, the organic insulating layer 12 is formed to planarize irregularities formed by the circuit layer 11.

The lower electrode LE1 of the subpixel SP1, the lower electrode LE2 of the subpixel SP2, and the lower electrode LE3 of the subpixel SP3 are provided on the organic insulating layer 12 and are spaced apart from each other.

The inorganic insulating layer 5 is provided on the organic insulating layer 12 and the lower electrodes LE1, LE2, and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2, and LE3 are covered with the inorganic insulating layer 5. The lower electrodes LE1, LE2, and LE3 are connected to the pixel circuits 1 of the respective subpixels SP1, SP2, and SP3 through the contact holes provided in the organic insulating layer 12. FIG. 3 omits the illustration of the contact holes in the organic insulating layer 12.

The partition 6 is formed in an overhang shape and comprises a lower portion 61 having conductivity and provided on the inorganic insulating layer 5 and an upper portion 62 provided on the lower portion 61.

In the illustrated example, the lower portion 61 comprises a bottom layer 63 provided on the inorganic insulating layer 5 and a stem layer 64 provided between the bottom layer 63 and the upper portion 62. The bottom layer 63 is thinner than the stem layer 64. The bottom layer 63 has the width greater than that of the stem layer 64. Both end portions of the bottom layer 63 protrude relative to the side surfaces of the stem layer 64.

The upper portion 62 is provided on the stem layer 64. In the illustrated example, the upper portion 62 comprises a thin film 65 provided on the stem layer 64 and a thin film 66 provided on the thin film 65. The upper portion 62 has the width greater than that of the stem layer 64. Both end portions of the upper portion 62 protrude relative to the side surfaces of the stem layer 64.

In the present specification, the side surfaces of the stem layer 64 are assumed to be the side surfaces of the stem layer 64 that extend between the bottom layer 63 and the upper portion 62. In the illustrated example, the upper portion 62 has the width greater than that of the bottom layer 63. The bottom layer 63 may have a width greater than that of the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and contacts the lower portion 61.

In the display element DE2, the organic layer OR2 contacts the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to have, of the bottom layer 63, the surface that directly contacts the stem layer 64 and the surface that protrudes relative to the stem layer 64 and faces the upper portion 62.

In the illustrated example, the subpixel SP1 further comprises the cap layer CP1 and a sealing layer SE11. The subpixel SP2 further comprises the cap layer CP2 and a sealing layer SE12. The subpixel SP3 further comprises the cap layer CP3 and a sealing layer SE13. The cap layers CP1, CP2 and CP3 function as optical adjustment layers, which improve the extraction efficiency of light emitted from the respective organic layers OR1, OR2, and OR3. The cap layers CP1, CP2, and CP3 may be omitted.

The cap layer CP1 is provided on the upper electrode UE1. The cap layer CP2 is provided on the upper electrode UE2. The cap layer CP3 is provided on the upper electrode UE3.

The sealing layer SE11 is provided on the cap layer CP1, contacts the partition 6, and continuously covers each member of the subpixel SP1. The sealing layer SE11 contacts the stem layer 64 and the upper portion 62 of the partition 6 surrounding the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 surrounding the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 surrounding the display element DE3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Each of the sealing layers SE11, SE12, and SE13 extends above the partition 6. The end portions of the sealing layers SE11, SE12 and SE13 are located above the partition 6. In the illustrated example, the sealing layer SE11 located on the partition 6 between the subpixels SP1 and SP2 is spaced apart from the sealing layer SE12 located on this partition 6. Further, the sealing layer SE11 located on the partition 6 between the subpixels SP1 and SP3 is spaced apart from the sealing layer SE13 located on this partition 6.

The bank BK is provided along the edge of the upper portion 62. The bank BK is formed as a convex body protruding in the third direction Z relative to the upper portion 62. Each of the sealing layers SE11, SE12, and SE13 overlaps the bank BK.

The stacked film FL1 is provided on the bank BK surrounding the display element DE1 and is covered with the sealing layer SE11. The stacked film FL2 is provided on the bank BK surrounding the display element DE2 and is covered with the sealing layer SE12. The stacked film FL3 is provided on the bank BK surrounding the display element DE3 and is covered with the sealing layer SE13.

Gaps GP are formed between the sealing layer SE11 and the partition 6, between the sealing layer SE12 and the partition 6, and between the sealing layer SE13 and the partition 6. Above the partition 6 between the subpixels SP1 and SP2, the gap GP surrounded by the partition 6, the sealing layer SE11, and the bank BK and the gap GP surrounded by the partition 6, the sealing layer SE12, and the bank BK are formed. Above the partition 6 between the subpixels SP1 and SP3, the gap GP surrounded by the partition 6, the sealing layer SE11, and the bank BK and the gap GP surrounded by the partition 6, the sealing layer SE13, and the bank BK are formed.

A transparent resin layer RS1 covers the partition 6 and the sealing layers SE11, SE12, and SE13. Further, the resin layer RS1 fills the gaps GP formed on the partition 6 and contacts the bank BK.

The sealing layer SE2 is provided on the resin layer RS1. A transparent resin layer RS2 is provided on the sealing layer SE2.

Each of the inorganic insulating layer 5, the sealing layers SE11, SE12, and SE13, the sealing layer SE2, and the bank BK is formed of, for example, an inorganic insulating material such as a silicon nitride (SiNx), a silicon oxide (SiOx), a silicon oxynitride (SiON) or an aluminum oxide (Al₂O₃). For example, the inorganic insulating layer 5 is formed of a silicon oxynitride, and each of the sealing layers SE11, SE12, SE13, and SE2 is formed of a silicon nitride. The bank BK is formed of a material different from the sealing layers SE11, SE12, and SE13. The bank BK is preferably formed of a material with lower etching rate than those of the sealing layers SE11, SE12, and SE13. For example, when the sealing layers SE11, SE12, and SE13 are formed of silicon nitrides, the bank BK is formed of a silicon oxynitride.

The lower portion 61 of the partition 6 is formed of a conductive material and is electrically connected to the upper electrodes UE1, UE2, and UE3. The bottom layer 63 is formed of, for example, a titanium-based material such as titanium or a titanium compound. The stem layer 64 is formed of a material different from those of the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material different from the stem layer 64. For example, the thin film 65 of the upper portion 62 is formed of a metal material such as a titanium-based material like titanium or a titanium compound. The thin film 66 is formed of an oxide conductive material such as an indium tin oxide (ITO).

Each of the lower electrodes LE1, LE2, and LE3 is, for example, a multilayer body having a transparent layer formed of an oxide conductive material such as an indium tin oxide (ITO) and a reflective layer formed of a metal material such as silver. For example, each of the lower electrodes LE1, LE2, and LE3 is a multilayer body having a reflective layer between a pair of transparent layers.

The organic layer OR1 has a light emitting layer EM1. The organic layer OR2 has a light emitting layer EM2. The organic layer OR3 has a light emitting layer EM3. The light emitting layers EM1, EM2, and EM3 are formed of materials different from each other. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range. The light emitting layer EM1 may be formed of a material that emits light in a green wavelength. The light emitting layer EM2 may be formed of a material that emits light in a blue wavelength.

Each of the organic layers OR1, OR2, and OR3 has a plurality of functional layers such as a hole injection layer, a hole transport layer, an electron blocking layer, a hole blocking layer, an electron transport layer, and an electron injection layer.

The upper electrodes UE1, UE2, and UE3 are formed of, for example, a metal material such as an alloy of magnesium and silver (MgAg).

Each of the cap layers CP1, CP2, and CP3 is a multilayer body consisting of a plurality of thin films. All of the thin films are transparent and have refractive indices different from each other.

The circuit layer 11, the organic insulating layer 12, the inorganic insulating layer 5, and the partition 6, which are illustrated, are provided across the display area DA and the surrounding area SA.

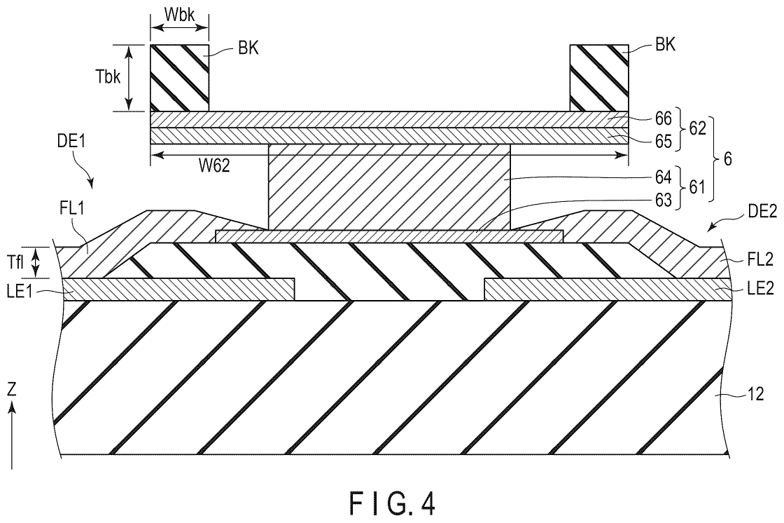

FIG. 4 is a cross-sectional view showing the partition 6 between the display element DE1 and the display element DE2 in an enlarged manner. FIG. 4 shows only elements necessary for explanations. Thus, the figure omits the illustration of the elements below the organic insulating layer 12, the elements above the stacked films FL1 and FL2, and the elements above the partition 6 and the bank BK.

The bank BK is provided on the thin film 66 of the upper portion 62. In the illustrated example, the bank BK is provided on a part protruding relative to the side surface of the stem layer 64 of the upper portion 62. A thickness Tbk along the third direction Z of the bank BK is greater than a thickness Tfl along the third direction Z of the stacked film FL1 (Tbk>Tfl). For example, the thicknesses of the stacked films FL1, FL2, and FL3 are 300 nm to 500 nm.

A width Wbk of the bank BK is less than half of a width W62 of the upper portion 62. Here, widths signify lengths in the direction orthogonal to the extending direction of the partition 6. The width W62 of the upper portion 62 corresponds to a distance between both end portions protruding relative to the side surfaces of the stem layer 64. For example, the width Wbk is 45 nm or more and is 5000 nm or less.

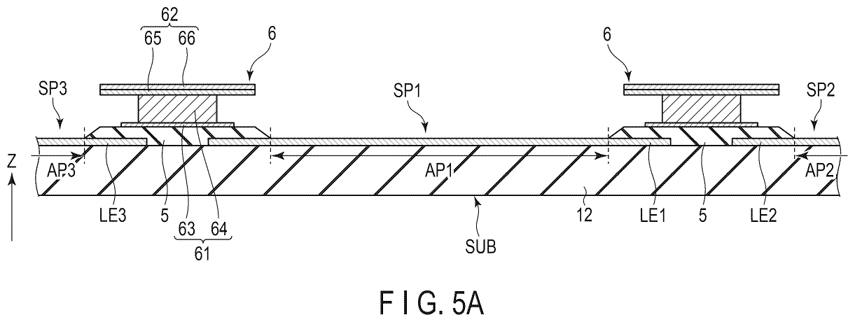

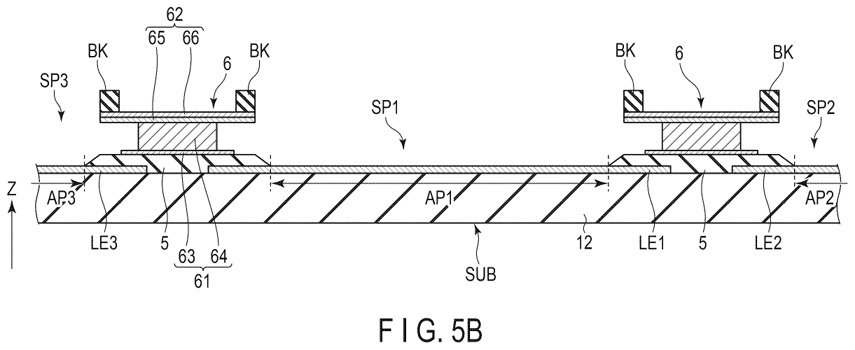

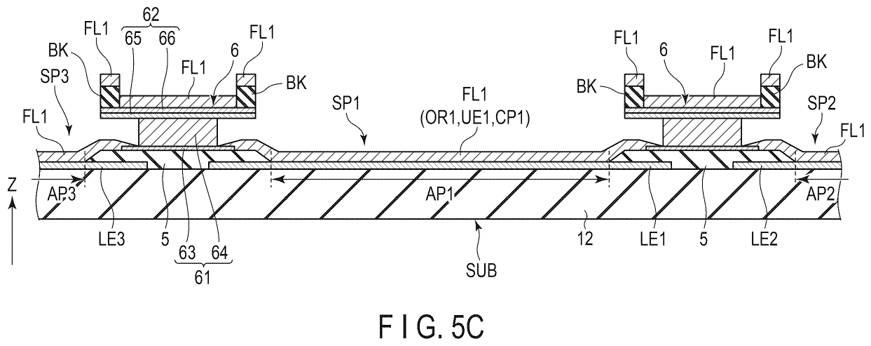

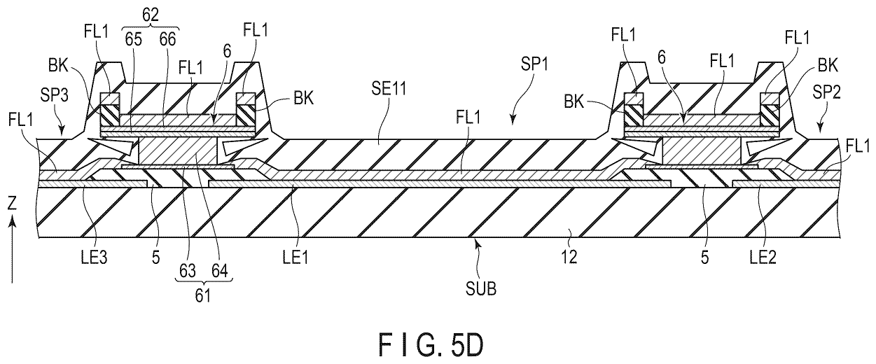

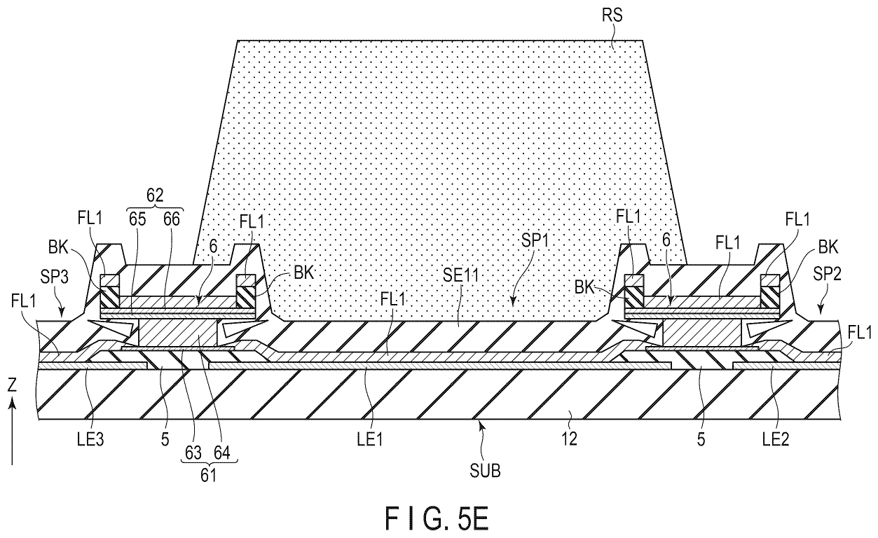

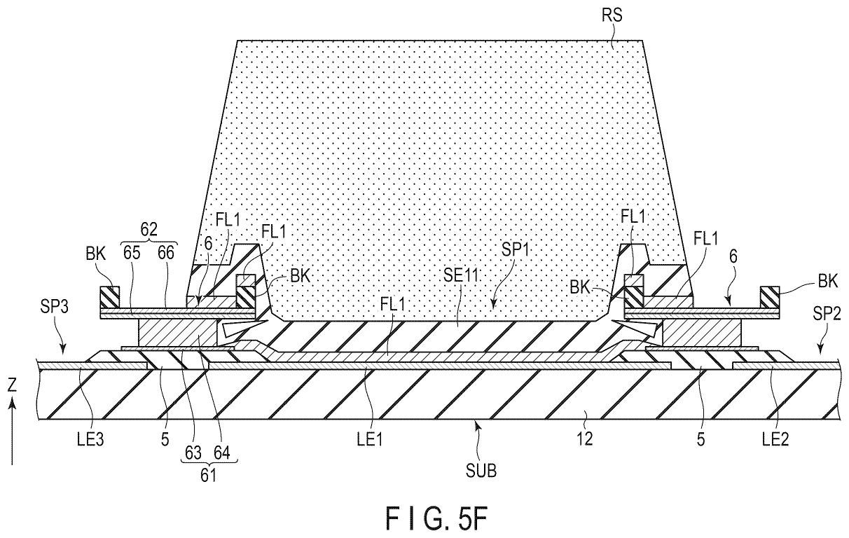

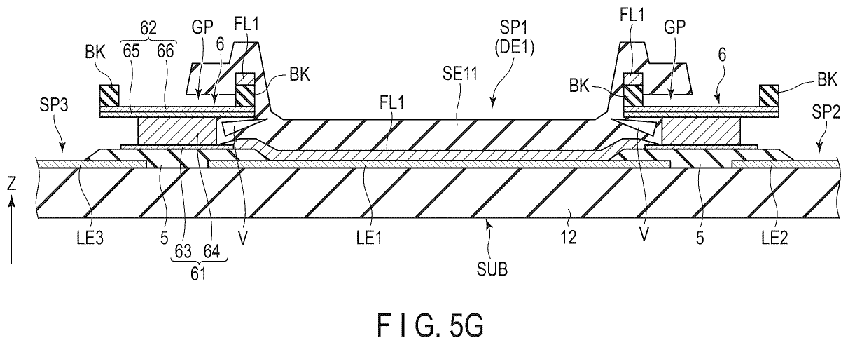

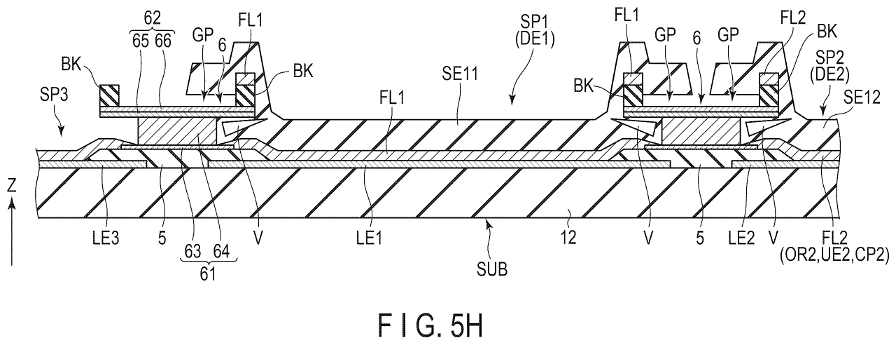

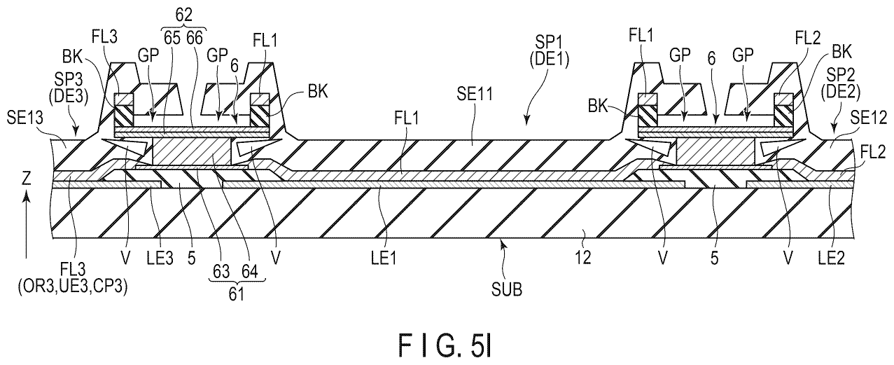

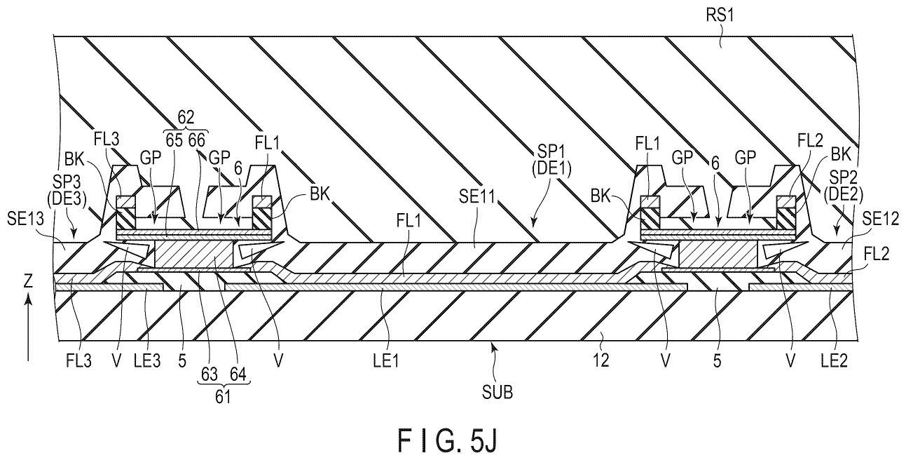

Next, the following will describe a manufacturing method of the display device DSP shown in FIG. 3. FIG. 5A to FIG. 5J are cross-sectional views of a processing substrate SUB along the A-B line of FIG. 2 and omits the illustration of the elements below the organic insulating layer 12.

First, as shown in FIG. 5A, the processing substrate SUB is prepared. The process of preparing the processing substrate SUB includes the process of forming the lower electrode LE1 of the subpixel SP1, the lower electrode LE2 of the subpixel SP2, and the lower electrode LE3 of the subpixel SP3 on the organic insulating layer 12, the process of forming the inorganic insulating layer 5 having the apertures AP1, AP2, and AP3 overlapping the respective lower electrodes LE1, LE2, and LE3, and the process of forming the partition 6 having an overhang shape and including the lower portion 61 located on the inorganic insulating layer 5 and the upper portion 62 located on the lower portion 61. The partition 6 may be formed after the formation of the inorganic insulating layer 5 having the apertures AP1, AP2, and AP3. Alternatively, the apertures AP1, AP2, and AP3 may be formed in the inorganic insulating layer 5 after the formation of the partition 6.

Subsequently, as shown in FIG. 5B, the bank BK is formed on the partition 6. The bank BK is formed in a loop shape as shown in FIG. 2. For example, the process of forming the bank BK includes a process of forming an inorganic insulating layer on the processing substrate SUB and a process of patterning this inorganic insulating layer. The inorganic insulating layer for forming the bank BK is formed by depositing inorganic insulating materials (for example, a silicon oxynitride) in a chemical vapor deposition (CVD) device.

Subsequently, the display element DE1 is formed.

First, as shown in FIG. 5C, vapor deposition using the partition 6 as a mask is performed to form the stacked film FL1 on the processing substrate SUB. The stacked film FL1 includes the organic layer OR1 including the light emitting layer EM1, the upper electrode UE1, and the cap layer CP1. The organic layer OR1, the upper electrode UE1, and the cap layer CP1 are successively formed by an evaporation device in a vacuum state. The stacked film FL1 is divided by the partition 6 having an overhang shape and the bank BK on the partition 6. That is, the stacked film FL1 is divided into parts overlapping the respective lower electrodes LE1, LE2, and LE3 within the area surrounded by the partition 6 and the bank BK, a part overlapping the bank BK above the partition 6, and a part not overlapping the bank BK above the partition 6 (the part contacting the thin film 66 of the upper part 62). As described above, the bank BK is thicker than the stacked film FL1. Therefore, the stacked film FL1 is divided above the partition 6.

Subsequently, as shown in FIG. 5D, the sealing layer SE11 continuously covering the stacked film FL1, the partition 6, and the bank BK is formed. The sealing layer SE11 is formed of an inorganic insulating material different from the bank BK. The sealing layer SE11 is formed by depositing inorganic insulating materials (for example, a silicon nitride) on the processing substrate SUB in a CVD device.

The stacked film FL1 and the sealing layer SE11 are substantially formed in the entire processing substrate SUB and are provided in the subpixels SP2 and SP3 as well as the subpixel SP1 in the display area DA.

Subsequently, as shown in FIG. 5E, a resist RS patterned into a predetermined shape is formed on the sealing layer SE11. The resist RS overlaps the subpixel SP1 and a part of the partition 6 around the subpixel SP1.

Subsequently, as shown in FIG. 5F, patterning is performed on the sealing layer SE11 and the stacked film FL1 using the resist RS as a mask. After removing the sealing layer SE11 exposed from the resist RS by performing various etching using the resist RS as a mask, the cap layer CP1, the upper electrode UE1, and the organic layer OR1 included in the stacked film FL1 are removed in series. Further, these patterning processes make the lower electrode LE2 of the subpixel SP2 and the lower electrode LE3 of the subpixel SP3 exposed.

Subsequently, as shown in FIG. 5G, the resist RS is removed. In this way, the display element DE1 in the subpixel SP1 is formed.

Further, a part not overlapping the bank BK, of the stacked film FL1 overlapping the partition 6, is removed in the processes between the patterning of the stacked film FL1 (FIG. 5F) and the removing of the resist RS (FIG. 5G). As a result, the gap GP surrounded by the sealing layer SE11, the partition 6, and the bank BK is formed.

When dry etching is performed on the sealing layer SE11, the etching rate of the bank BK is lower than that of the sealing layer SE11. Thus, the etching progress forming the gap GP stops at the bank BK. That is, the bank BK functions as an etching stopper. Thus, the gap GP never connects to a void V formed in the sealing layer SE11.

Furthermore, the stacked film FL1 overlapping the bank BK is covered with the sealing layer SE11, is spaced apart from the part not overlapping the bank BK, is not removed by the etching, and thus remains.

Subsequently, as shown in FIG. 5H, the display element DE2 is formed. The procedure of forming the display element DE2 is the same as that of forming the display element DE1. That is, the stacked film FL2 is formed on the lower electrode LE2. The stacked film FL2 includes the organic layer OR2 including the light emitting layer EM2, the upper electrode UE2, and the cap layer CP2. Subsequently, the sealing layer SE12 is formed on the stacked film FL2. Subsequently, a resist is formed on the sealing layer SE12. Then, patterning using this resist as a mask is performed. In this way, the sealing layer SE12 and the stacked film FL2 exposed from the resist are sequentially removed. Subsequently, the resist is removed.

This process forms the display element DE2 in the subpixel SP2 and makes the lower electrode LE3 of the subpixel SP3 exposed. Furthermore, a part not overlapping the bank BK, of the stacked film FL2 on the partition 6, is removed in the patterning. As a result, the gap GP surrounded by the sealing layer SE12, the partition 6, and the bank BK is formed.

In the formation of the display element DE2, the gap GP formed between the sealing layer SE11 and the partition 6 is subjected to the second etching step following the process of forming the display element DE1. However, the bank BK functioning as the etching stopper suppresses the expansion of the gap GP as described above.

Subsequently, as shown in FIG. 5I, the display element DE3 is formed. The procedure of forming the display element DE3 is the same as that of forming the display element DE1. That is, the stacked film FL3 is formed on the lower electrode LE3. The stacked film FL3 includes the organic layer OR3 including the light emitting layer EM3, the upper electrode UE3, and the cap layer CP3. Subsequently, the sealing layer SE13 is formed on the stacked film FL3. Subsequently, a resist is formed on the sealing layer SE13. Then, patterning using this resist as a mask is performed. In this way, the sealing layer SE13 and the stacked film FL3 exposed from the resist are sequentially removed. Subsequently, the resist is removed.

This process forms the display element DE3 in the subpixel SP3. Furthermore, a part not overlapping the bank BK, of the stacked film FL3 on the partition 6, is removed in the patterning. As a result, the gap GP surrounded by the sealing layer SE13, the partition 6, and the bank BK is formed.

In the formation of the display element DE3, the gap GP formed between the sealing layer SE11 and the partition 6 is subjected to the third etching step following the process of forming the display element DE1 and the process of forming the display element DE2. However, the bank BK functioning as the etching stopper suppresses the expansion of the gap GP as described above.

Similarly, the gap GP formed between the sealing layer SE12 and the partition 6 is subjected to the second etching step following the process of forming the display element DE2. However, the bank BK functioning as the etching stopper suppresses the expansion of the gap GP as described above.

The above-described manufacturing process assumes a case where the display element DE1 is formed firstly, and the display element DE2 is formed secondly, and the display element DE3 is formed lastly. However, the formation order of the display elements DE1, DE2, and DE3 is not limited to this example.

Then, as shown in FIG. 5J, an organic insulating material is applied and cured to form the resin layer RS1 covering the sealing layers SE11, SE12, and SE13. The resin layer RS1 fills the gaps GP formed between the partition 6 and the sealing layer SE11, between the partition 6 and the sealing layer SE12, and between the partition 6 and the sealing layer SE13 and contacts the bank BK.

Then, the sealing layer SE2 is formed by depositing an inorganic insulating material (for example, a silicon nitride). Then, an organic insulating material is applied and cured to form the resin layer RS2.

The display device DSP is completed through these processes.

As described above, the expansion of the gaps GP due to a plurality of etching processes and the connection between the gap GP and the void V are suppressed. Thus, the formation of the moisture intrusion paths to the display elements DE1, DE2, and DE3 is suppressed. Therefore, the degradation of the display elements DE1, DE2, and DE3 due to moisture is suppressed, thereby suppressing decreases in the reliability.

Next, the following will describe other configuration examples. The same elements as in the above configuration example are denoted by the same reference numerals and their detailed explanations are omitted in some cases.

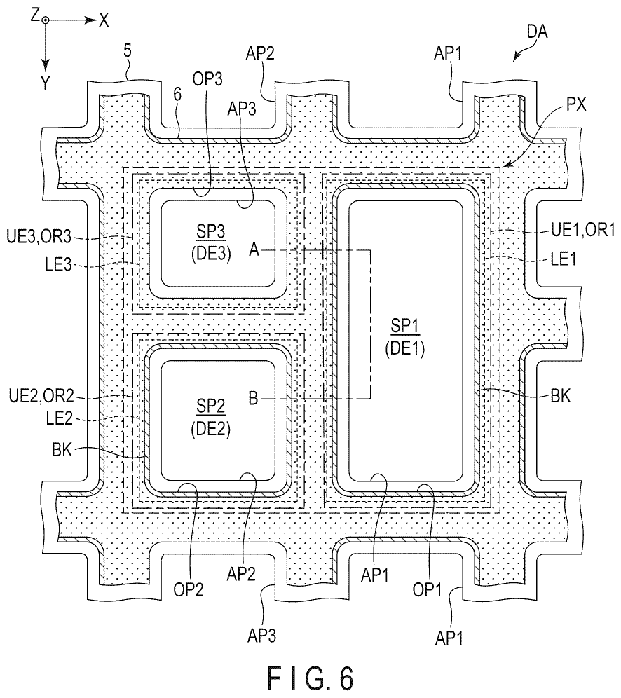

FIG. 6 is a view showing another configuration example of the layout of the bank BK.

The configuration example shown in FIG. 6 differs from the configuration example shown in FIG. 2 in that the bank BK surrounding the display element DE1 and the bank BK surrounding the display the element DE2 are provided, but the bank surrounding the display element DE3 is not provided.

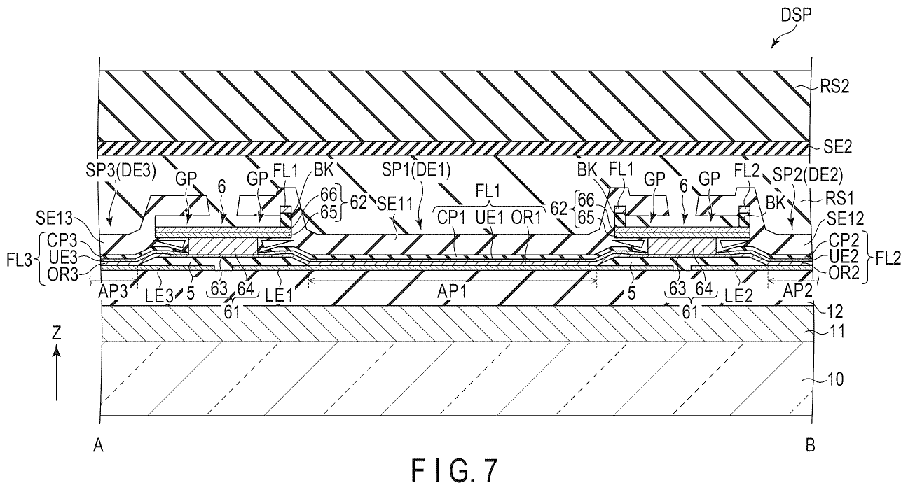

FIG. 7 is a schematic cross-sectional view of the display device DSP along the A-B line of FIG. 6.

Above the partition 6 between the subpixels SP1 and SP2, each of the bank BK surrounding the display element DE1 and the bank BK surrounding the display element DE2 is provided along the edge of the upper portion 62. The stacked film FL1 is provided on the bank BK surrounding the display element DE1 and is covered with the sealing layer SE11. The stacked film FL2 is provided on the bank BK surrounding the display element DE2 and is covered with the sealing layer SE12. The gap GP surrounded by the partition 6, the sealing layer SE11, and the bank BK and the gap GP surrounded by the partition 6, the sealing layer SE12, and the bank BK are formed.

Above the partition 6 between the subpixels SP1 and SP3, the bank BK surrounding the display element DE1 is provided along the edge of the upper portion 62. The stacked film FL1 is provided on the bank BK and is covered with the sealing layer SE11. In contrast, the stacked film FL3 is not provided above the partition 6. The gap GP surrounded by the partition 6, the sealing layer SE11, and the bank BK and the gap GP surrounded by the partition 6 and the sealing layer SE13 are formed.

The resin layer RS1 covers the partition 6 and the sealing layers SE11, SE12, and SE13 and fills the gap GP.

As described with reference to FIG. 5C to FIG. 5I, when the display element DE3 is formed after the formation of the display elements DE1 and DE2, the gap GP formed between the partition 6 and the sealing layer SE13 is not subjected to etching processes for forming other display elements. Thus, the configuration examples shown in FIG. 6 and FIG. 7 can achieve the same effects as the above configuration examples even though the bank BK surrounding the display element DE3 is not provided.

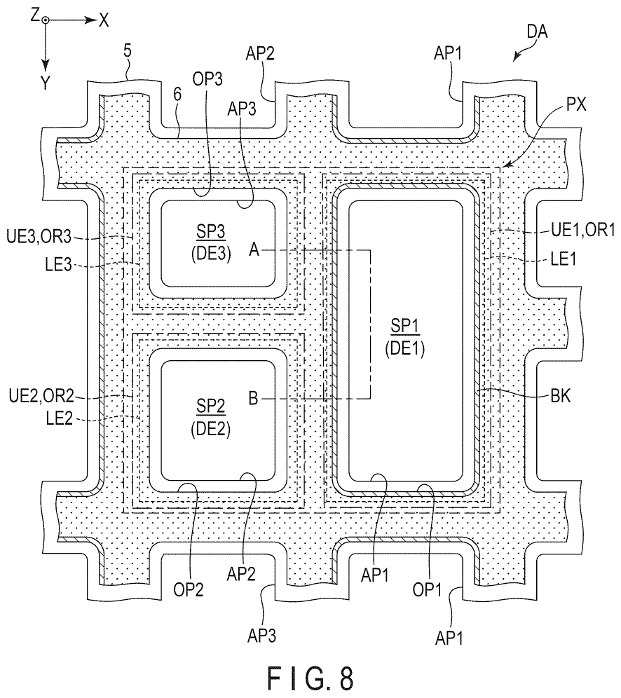

FIG. 8 is a view showing another configuration example of the layout of the bank BK.

The configuration example shown in FIG. 8 differs from the configuration example shown in FIG. 2 in that the bank BK surrounding the display element DE1 is provided, but the bank BK surrounding the display element DE2 and the bank surrounding the display element DE3 are not provided.

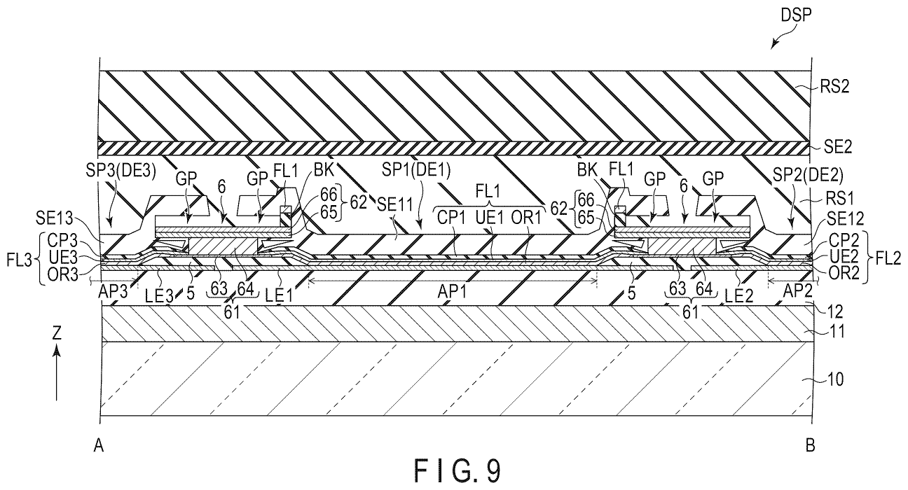

FIG. 9 is a schematic cross-sectional view of the display device DSP along the A-B line of FIG. 8.

Above the partition 6 between the subpixels SP1 and SP2, the bank BK surrounding the display element DE1 is provided along the edge of the upper portion 62. The stacked film FL1 is provided on the bank BK and is covered with the sealing layer SE11. In contrast, the stacked film FL2 is not provided above the partition 6. The gap GP surrounded by the partition 6, the sealing layer SE11, and the bank BK and the gap GP surrounded by the partition 6 and the sealing layer SE12 are formed.

Above the partition 6 between the subpixels SP1 and SP3, the bank BK surrounding the display element DE1 is provided along the edge of the upper portion 62. The stacked film FL1 is provided on the bank BK and is covered with the sealing layer SE11. In contrast, the stacked film FL3 is not provided above the partition 6. The gap GP surrounded by the partition 6, the sealing layer SE11, and the bank BK and the gap GP surrounded by the partition 6 and the sealing layer SE13 are formed.

The resin layer RS1 covers the partition 6 and the sealing layers SE11, SE12, and SE13 and fills the gap GP.

As described with reference to FIG. 5C to FIG. 5I, when the display element DE2 is formed after the formation of the display element DE1 and the display element DE3 is formed after the formation of the display element DE2, the gap GP formed between the partition 6 and the sealing layer SE11 is subjected to etching processes for forming the other display elements DE2 and DE3. In contrast, the gap GP formed between the partition 6 and the sealing layer SE12 is subjected to etching for forming the other display element DE3, and the gap GP formed between the partition 6 and the sealing layer SE13 is not subjected to etching for forming the other display elements.

The gap GP between the partition 6 and the sealing layer SE12, and the gap between the partition 6 and the sealing layer SE13 are subjected to etching fewer times compared to the gap between the partition 6 and the sealing layer SE11. Thus, the configuration examples shown in FIG. 8 and FIG. 9 can achieve the same effects as the above configuration examples even though the banks BK surrounding the display elements DE2 and DE3 are not provided.

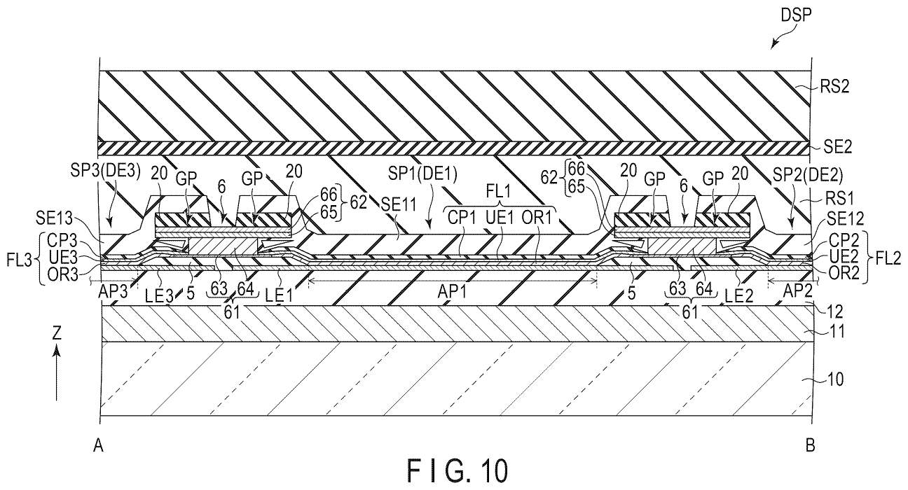

FIG. 10 is a view showing another configuration example of the display device DSP. The cross-sectional view of FIG. 10 corresponds to the cross-sectional view of the display device DSP along the A-B line of FIG. 2. However, the bank BK shown in FIG. 2 is not provided in the configuration shown in FIG. 10.

The display device DSP comprises a filler 20 filling the gap GP. The filler 20 is formed of a resin material different from the resin layer RS1. For example, the filler 20 is formed of a photosensitive resin such as a polyimide. The resin layer RS1 is formed of an epoxy resin or an acrylic resin.

None of the stacked film FL1 and the stacked film FL2 are provided above the partition 6 between the subpixels SP1 and SP2. The filler 20 fills the gap GP surrounded by the partition 6 and the sealing layer SE11 and the gap surrounded by the partition 6 and the sealing layer SE12. The resin layer RS1 does not fill the gap GP, but contacts the filler 20 and contacts the upper portion 62 of the partition 6 between the fillers 20 adjacent to each other.

None of the stacked film FL1 and the stacked film FL3 are provided above the partition 6 between the subpixels SP1 and SP3. The filler 20 fills the gap GP surrounded by the partition 6 and the sealing layer SE11 and the gap GP surrounded by the partition 6 and the sealing layer SE13. The resin layer RS1 does not fill the gap GP, but contacts the filler 20 and contacts the upper portion 62 of the partition 6 between the fillers 20 adjacent to each other.

The sealing layer SE2 is provided on the resin layer RS1. The resin layer RS2 is provided on the sealing layer SE2.

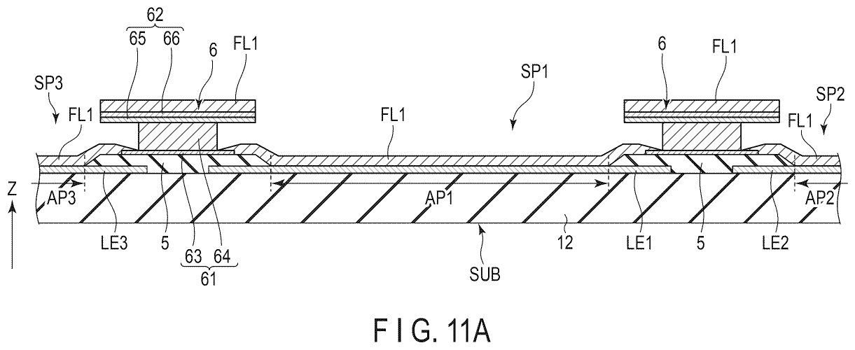

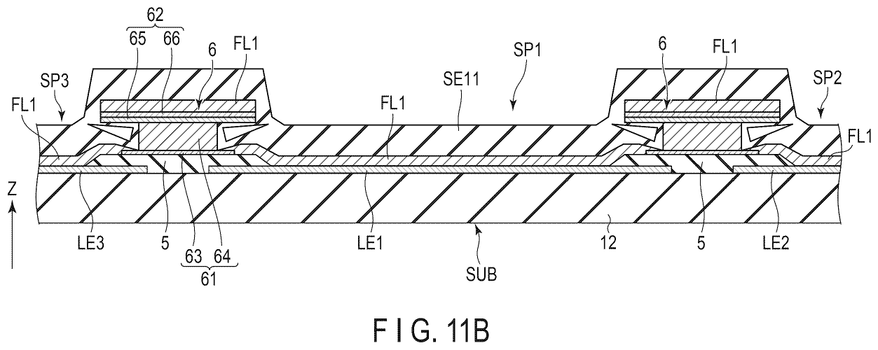

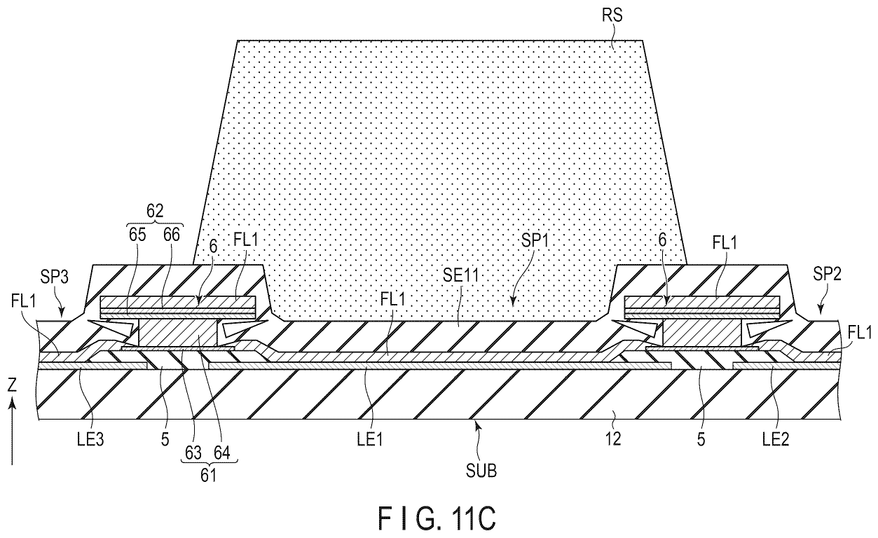

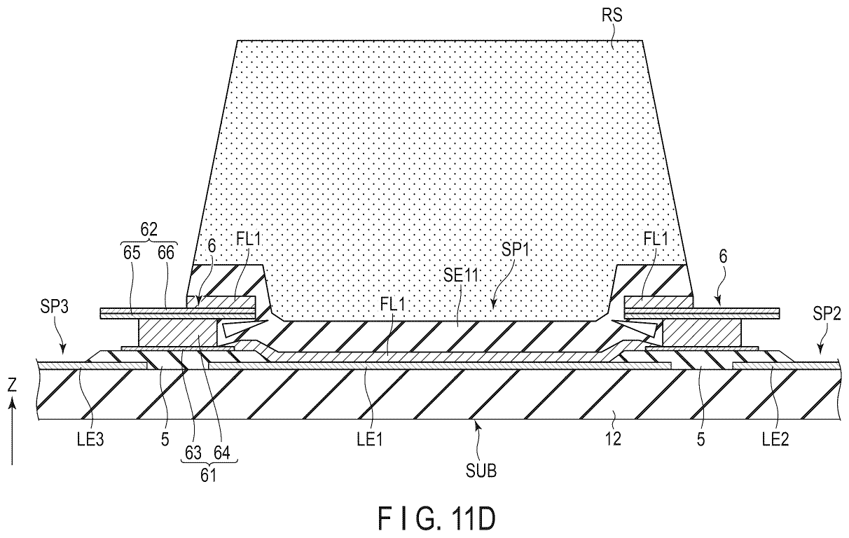

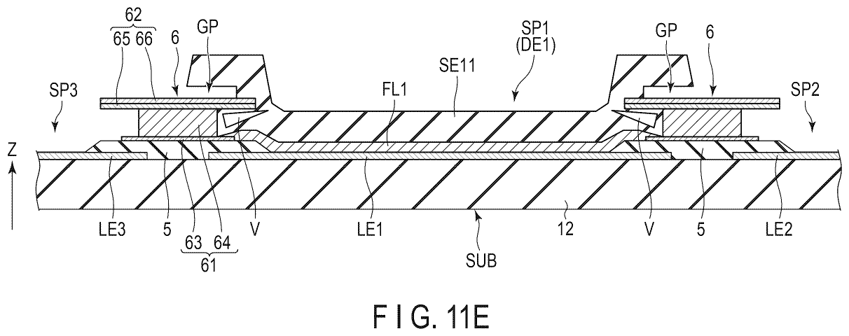

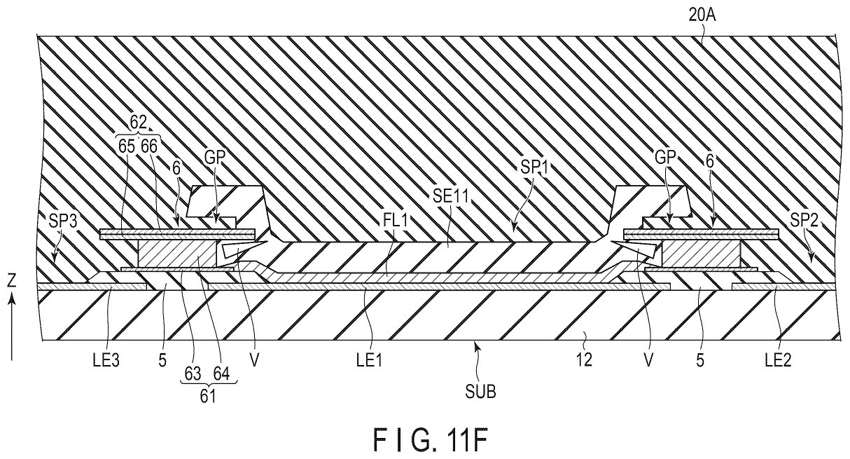

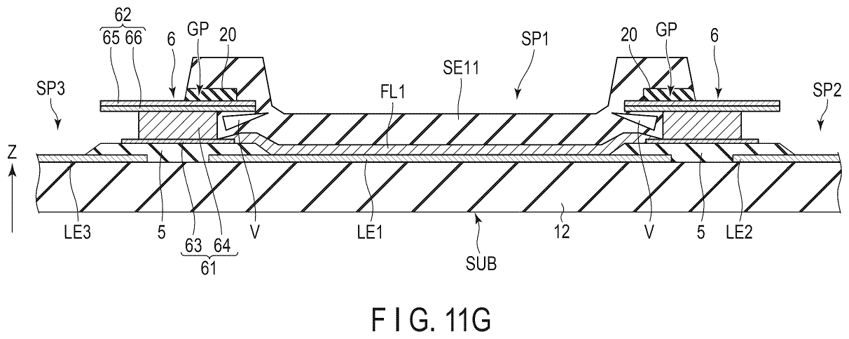

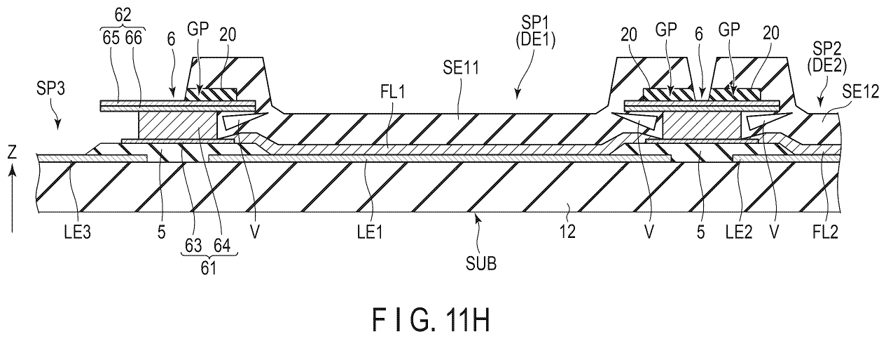

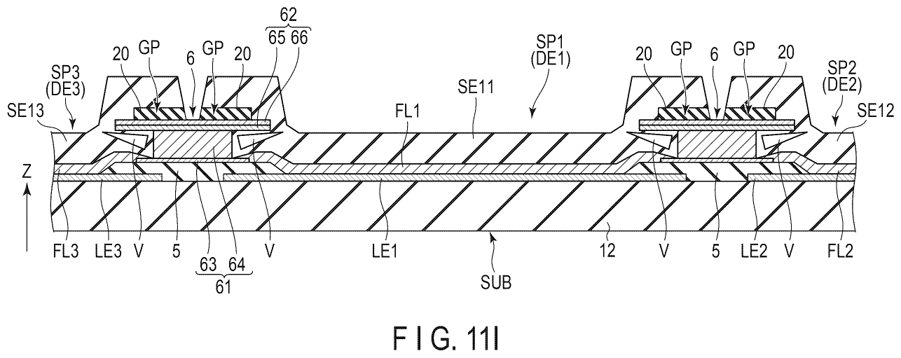

Next, the following will describe a manufacturing method of the display device DSP shown in FIG. 10. FIG. 11A to FIG. 11I omit the illustration of the elements below the organic insulating layer 12.

First, as shown in FIG. 11A, a processing substrate SUB is prepared. The process of preparing the processing substrate SUB includes the process of forming the lower electrode LE1 of the subpixel SP1, the lower electrode LE2 of the subpixel SP2, and the lower electrode LE3 of the subpixel SP3 on the organic insulating layer 12, the process of forming the inorganic insulating layer 5 having the apertures AP1, AP2, and AP3 overlapping the respective lower electrodes LE1, LE2, and LE3, and the process of forming the partition 6 having an overhang shape and including the lower portion 61 located on the inorganic insulating layer 5 and the upper portion 62 located on the lower portion 61.

Subsequently, vapor deposition using the partition 6 as a mask is performed to form the stacked film FL1 on the processing substrate SUB. The stacked film FL1 includes the organic layer OR1 including the light emitting layer EM1, the upper electrode UE1, and the cap layer CP1 as described with reference to FIG. 5C. The stacked film FL1 is divided by the partition 6 having an overhang shape. Specifically, the stacked film FL1 is divided into parts overlapping the respective lower electrodes LE1, LE2, and LE3 within the area surrounded by the partition 6 and a part overlapping the partition 6.

Subsequently, as shown in FIG. 11B, the sealing layer SE11 continuously covering the stacked film FL1 and the partition 6 is formed. For example, the sealing layer SE11 is formed by depositing a silicon nitride.

Subsequently, as shown in FIG. 11C, the resist RS patterned into a predetermined shape is formed on the sealing layer SE11. The resist RS overlaps the subpixel SP1 and a part of the partition 6 around the subpixel SP1.

Subsequently, as shown in FIG. 11D, patterning is performed on the sealing layer SE11 and the stacked film FL1 using the resist RS as a mask. After removing the sealing layer SE11 exposed from the resist RS by performing various etching using the resist RS as a mask, the cap layer CP1, the upper electrode UE1, and the organic layer OR1 included in the stacked film FL1 are removed in series. Further, these patterning processes make the lower electrode LE2 of the subpixel SP2 and the lower electrode LE3 of the subpixel SP3 exposed.

Subsequently, as shown in FIG. 11E, the resist RS is removed. As a result, the display element DE1 in the subpixel SP1 is formed.

The stacked film FL1 overlapping the partition 6 is removed in the processes between the patterning of the stacked film FL1 (FIG. 11D) and the removing of the resist RS (FIG. 11E). Thus, the gap GP is formed between the sealing layer SE11 and the partition 6.

Subsequently, as shown in FIG. 11F, a photosensitive resin 20A (for example, a polyimide) is applied onto the entire surface of the substrate SUB. At this time, the applied photosensitive resin 20A fills the gap GP. Then, the photosensitive resin 20A is pre-baked. Then, the photosensitive resin 20A is exposed to light.

Subsequently, as shown in FIG. 11G, the photosensitive resin is developed and baked. As a result, the filler 20 filling the gap GP is formed. Further, other photosensitive resins are removed.

Subsequently, as shown in FIG. 11H, the display element DE2 is formed. The procedure of forming the display element DE2 is the same as that of forming the display element DE1. That is, the stacked film FL2 is formed on the lower electrode LE2. The stacked film FL2 includes the organic layer OR2 including the light emitting layer EM2, the upper electrode UE2, and the cap layer CP2. Subsequently, the sealing layer SE12 is formed on the stacked film FL2. Subsequently, a resist is formed on the sealing layer SE12. Then, patterning using this resist as a mask is performed. This sequentially removes the sealing layer SE12 and the stacked film FL2 exposed from the resist. Subsequently, the resist is removed.

This process forms the display element DE2 in the subpixel SP2 and makes the lower electrode LE3 of the subpixel SP3 exposed. Further, the stacked film FL2 on the partition 6 is removed at the time of patterning. As a result, the gap GP between the sealing layer SE12 and the partition 6 is formed. Subsequently, the filler 20 is formed in the gap GP between the sealing layer SE12 and the partition 6 by patterning a photosensitive resin as described with reference to FIG. 11F and FIG. 11G.

In the formation of this display element DE2, the gap GP between the sealing layer SE11 and the partition 6 is protected by the filler 20. Thus, the expansion of the gap GP is suppressed.

Subsequently, as shown in FIG. 11I, the display element DE3 is formed. The procedure of forming the display element DE3 is the same as that of forming the display element DE1. That is, the stacked film FL3 is formed on the lower electrode LE3. The stacked film FL3 includes the organic layer OR3 including the light emitting layer EM3, the upper electrode UE3, and the cap layer CP3. Subsequently, the sealing layer SE13 is formed on the stacked film FL3. Subsequently, a resist is formed on the sealing layer SE13. Then, patterning using this resist as a mask is performed. This sequentially removes the sealing layer SE13 and the stacked film FL3 exposed from the resist. Subsequently, the resist is removed.

As a result, the display element DE3 in the subpixel SP3 is formed. Further, the stacked film FL3 on the partition 6 is removed at the time of patterning. As a result, the gap GP between the sealing layer SE13 and the partition 6 is formed. Subsequently, the filler 20 is formed in the gap GP between the sealing layer SE13 and the partition 6 by patterning a photosensitive resin as described with reference to FIG. 11F and FIG. 11G.

In the formation of this display element DE3, each of the gap GP between the sealing layer SE11 and the partition 6 and the gap GP between the sealing layer SE12 and the partition 6 is protected by the filler 20. Thus, the expansion of the gap GP is suppressed.

Subsequently, the resin layer RS1 is formed on the sealing layers SE11, SE12, and SE13. Then, the sealing layer SE2 is formed on the resin layer RS1. Then, the resin layer RS2 is formed on the sealing layer SE2.

The display device DSP is completed through these processes.

As described above, the above configuration can suppress the expansion of the gap GP on the partition 6 and connection of the gap GP and the void V. Thus, the formation of the moisture intrusion paths to the display elements is suppressed. Therefore, the degradation of the display elements due to the moisture is suppressed, thereby suppressing decreases in the reliability.

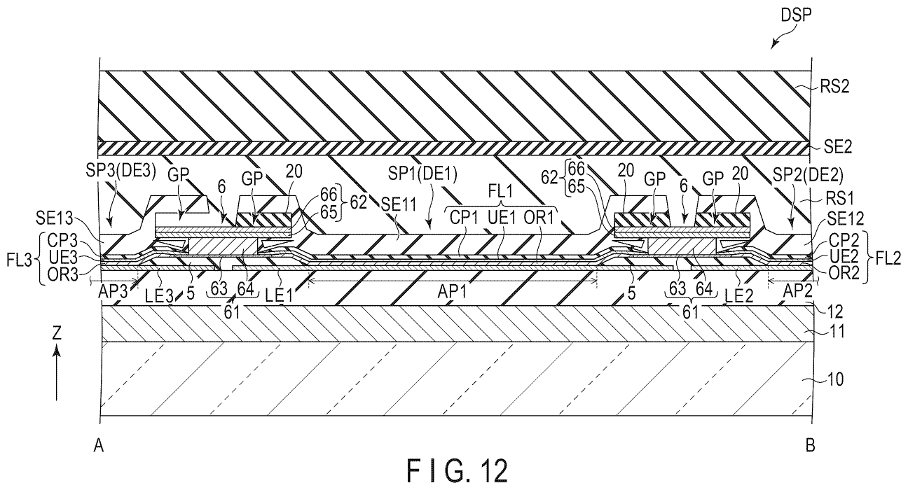

FIG. 12 is a view showing a configuration example of the display device DSP.

The configuration example shown in FIG. 12 differs from the configuration example shown in FIG. 10 in that the filler 20 is not provided in the gap GP between the partition 6 and the sealing layer SE13. The filler 20 is provided in each of the gap GP between the partition 6 and the sealing layer SE11 and the gap GP between the partition 6 and the sealing layer SE12.

As explained with reference to FIG. 11A to FIG. 11I, when the display element DE3 is formed after the formation of the display elements DE1 and DE2, the gap GP formed between the partition 6 and the sealing layer SE13 is not subjected to etching for forming other display elements. Thus, the configuration example shown in FIG. 12 can achieve the same effects as the above configuration examples even though the filler 20 between the partition 6 and the sealing layer SE13 is not provided.

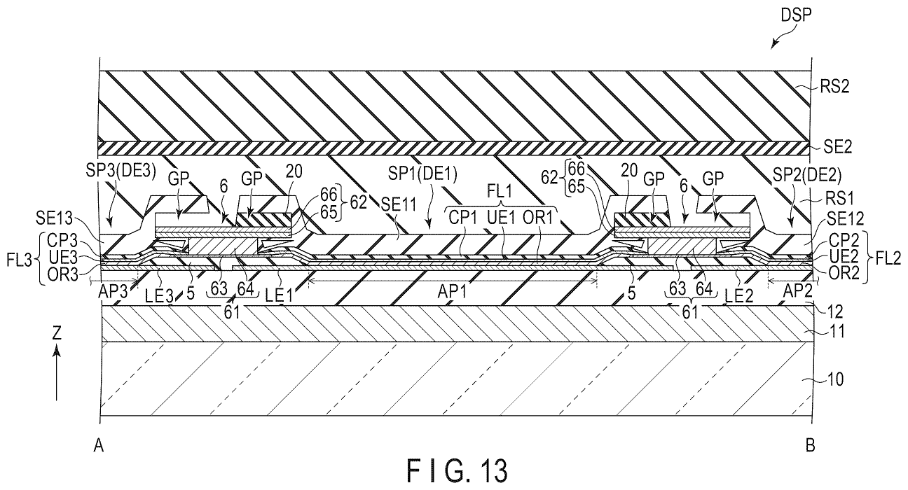

FIG. 13 is a view showing a configuration example of the display device DSP.

The configuration example shown in FIG. 13 differs from the configuration example shown in FIG. 10 in that the filler 20 is not provided in the gap GP between the partition 6 and the sealing layer SE12 and the gap between the partition 6 and the sealing layer SE13. The filler 20 is provided in the gap GP between the partition 6 and the sealing layer SE11.

As described with reference to FIG. 11A to 11I, when the display element DE2 is formed after the formation of the display element DE1 and the display element DE3 is formed after the formation of the display element DE2, the gap GP between the partition 6 and the sealing layer SE12, and the gap between the partition 6 and the sealing layer SE13 are subjected to etching fewer times compared to the gap between the partition 6 and the sealing layer SE11. Thus, the configuration example shown in FIG. 13 can achieve the same effects as the above configuration examples even though the filler 20 between the partition 6 and the sealing layer SE12 and the filler 20 between the partition 6 and the sealing layer SE13 are not provided.

For example, in the above embodiments, the sealing layers SE11, SE12, and SE13 correspond to the first sealing layer, the resin layer RS1 corresponds to the first resin layer, the sealing layer SE2 corresponds to the second sealing layer, and the resin layer RS2 corresponds to the second resin layer.

The display element DE3 is a red display element configured to emit red light. The display element DE2 is a green display element configured to emit green light but may be a blue display element configured to emit blue light. The display element DE1 is the blue display element but may be the green display element.

As described above, the present embodiment can provide a display device which can suppress decreases in reliability and a manufacturing method of the same.

All of the display devices and manufacturing methods thereof that can be implemented by a person of ordinary skill in the art through arbitrary design changes to the display device and manufacturing method thereof disclosed above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A display device comprising:
a substrate;
a display element provided above the substrate;
an inorganic insulating layer having an aperture overlapping the display element;
a partition provided on the inorganic insulating layer, formed in an overhang shape, and surrounding the display element;
a bank provided on the partition and surrounding
a first sealing layer formed of an inorganic insulating material, overlapping the display element and the bank, extending above the partition, and forming a gap between the first sealing layer and the partition.

2. The display device of claim 1, further comprising:
a stacked film spaced apart from the display element, provided on the bank, and covered with the first sealing layer, wherein
the display element includes:
a lower electrode having a peripheral portion covered with the inorganic insulating layer;
an organic layer provided on the lower electrode in the aperture and including a light emitting layer;
an upper electrode provided on the organic layer; and
a cap layer provided on the upper electrode and covered with the first sealing layer, and
the stacked film includes a thin film formed of the same materials as each of the organic layer, the upper electrode, and the cap layer.

3. The display device of claim 2, wherein the bank is thicker than the stacked film.

4. The display device of claim 2, wherein
the partition comprises:
a lower portion provided on the inorganic insulating layer, formed of a conductive material, and contacting the upper electrode; and
an upper portion provided on the lower portion, and
the bank is provided along an edge of the upper portion.

5. The display device of claim 4, wherein
the lower portion comprises:
a bottom layer provided on the inorganic insulating layer; and
a stem layer provided between the bottom layer and the upper portion, and
both end portions of the bottom layer and both end portions of the upper portion protrude relative to side surfaces of the stem layer.

6. The display device of claim 5, wherein
a width of the bank is less than half of a width of the upper portion.

7. The display device of claim 1, further comprising:
a first resin layer provided on the first sealing layer and filling the gap;
a second sealing layer formed of an inorganic insulating material and provided on the first resin layer; and
a second resin layer provided on the second sealing layer.

8. The display device of claim 1, wherein
the bank is formed of an inorganic insulating material different from the first sealing layer.

9. The display device of claim 8, wherein
the first sealing layer is formed of a silicon nitride, and
the bank is formed of a silicon oxynitride.

10. The display device of claim 1, further comprising:
a red display element provided above the substrate, adjacent to the display element, and configured to emit red light, wherein
a bank surrounding the red display element is not provided.

11. A display device comprising:
a substrate;
a display element provided above the substrate;
an inorganic insulating layer having an aperture overlapping the display element;
a partition provided on the inorganic insulating layer, formed in an overhang shape, and surrounding the display element;
a first sealing layer formed of an inorganic insulating material, overlapping the display element, extending above the partition, and forming a gap between the first sealing layer and the partition;
a filler filling the gap; and
a first resin layer provided on the first sealing layer and formed of a material different from the filler.

12. The display device of claim 11, further comprising:
a second sealing layer formed of an inorganic insulating material and provided on the first resin layer; and
a second resin layer provided on the second sealing layer.

13. The display device of claim 11, wherein
the filler is formed of a polyimide.

14. The display device of claim 1, wherein
the display element is a blue display element configured to emit blue light or a green display element configured to emit green light.

15. A display device manufacturing method, the method comprising steps of:
preparing a processing substrate by forming a lower electrode above a substrate, forming an inorganic insulating layer covering a periphery portion of the lower electrode, and forming a partition having an overhang shape and located on the inorganic insulating layer;
forming a loop-shaped bank on the partition;
performing a vapor deposition using the partition as a mask to form a stacked film including an organic layer including a light emitting layer, an upper electrode, and a cap layer, the stacked film being divided into a part overlapping the lower electrode within an area surrounded by the partition and the bank, a part overlapping the bank above the partition, and a part not overlapping the bank above the partition;
depositing an inorganic insulating material to form a first sealing layer covering the stacked film, the partition, and the bank;
forming a resist patterned into a predetermined shape on the first sealing layer;
patterning the first sealing layer and the stacked film using the resist as a mask; and
removing the resist.

16. The manufacturing method of claim 15, wherein
the part not overlapping the bank above the partition, of the stacked film, is removed, in processes between the patterning of the first stacked film and the removing of the resist; and
a gap surrounded by the partition, the first sealing layer, and the bank, is formed.

17. The manufacturing method of claim 15, wherein
the bank is formed from an inorganic insulating material different from the first sealing layer, and
an etching rate of the bank is smaller than an etching rate of the first sealing layer.

18. The manufacturing method of claim 16, further comprising a step of:
forming a first resin layer covering the first sealing layer after the removing of the resist, wherein
the first resin layer fills the gap.

19. A display device manufacturing method, the method comprising steps of:
preparing a processing substrate by forming a lower electrode above a substrate, forming an inorganic insulating layer covering a periphery portion of the lower electrode, and forming a partition having an overhang shape and located on the inorganic insulating layer;
performing a vapor deposition using the partition as a mask to form a stacked film including an organic layer including a light emitting layer, an upper electrode, and a cap layer, the stacked film being divided into a part overlapping the lower electrode within an area surrounded by the partition and a part overlapping the partition;
depositing an inorganic insulating material to form a first sealing layer covering the stacked film and the partition;
forming a resist patterned into a predetermined shape on the first sealing layer;
patterning the first sealing layer and the stacked film using the resist as a mask;
removing the resist; and
filling a gap formed between the partition and the first sealing layer with a filler, the gap being formed by removing the part overlapping the partition of the stacked film.

20. The manufacturing method of claim 19, wherein
the step of filling the filler includes steps of:
coating a photosensitive resin over the entire surface of the processing substrate;
exposing the photosensitive resin to light; and
developing the photosensitive resin.
